(19) United States
(12) Patent Application Publication
(10) Pub. No.: US 2007/0165764 A1
(43) Pub. Date: Jul. 19, 2007

(54) Phase conjugate circuit

(76) Inventors: Vincent Francis Fusco, Belfast (GB); Thorsten Brabetz, Belfast (GB); Neil Buchanan, Belfast (GB)

Correspondence Address: Gregory J Lavorgna;Drinker Buiddle and Reath, One Logan Square, 18th and Cherry Streets, Philadelphia, PA, 19103, US

(21) Appl. No.: 10/573,678

(22) PCT Filed: Sep. 23, 2004
(86) PCT No.: PCT/GB04/04045

§ 371 Date: Nov. 20, 2006

(30) Foreign Application Priority Data
Sep. 26, 2003 (GB) 0322538.0

(51) Int. Cl. H03D 3/24

(52) U.S. Cl. 375/376

(57) ABSTRACT

A phase conjugate circuit is disclosed for deriving phase conjugation information from a main input signal of a given frequency comprising: an input receiving a reference input signal; at least one phase locked loop circuit comprising an oscillator having a main output signal, an input receiving a PLL input signal, an input receiving a feedback signal from the oscillator and at least one phase detecting means, wherein the phase detection means detects any phase difference between the PLL input is signal and the feedback signal and provides a phase control signal to the oscillator. Ion one embodiment, the main input signal is mixed with the main out put signal to provide the feedback signal and the reference signal is the PLL input signal. In an alternative embodiment, the reference signal is mixed with the main output signal to produce the feedback signal and the main input signal is the PLL input signal. In a further alternative embodiment, the main input signal is mixed with the reference signal to provide the PLL input signal and the main output signal is the feedback signal.

This invention relates generally to phase conjugate circuits and specifically, but not exclusively, to phase conjugate circuits containing phase locked loop circuits.

Phase conjugation of a particular signal is useful in numerous applications. One example is in retro-directive antenna arrays, where an incoming signal is automatically re-transmitted in the same direction as it was incident on the array by transmitting the phase conjugate of the incoming signal. Another example is in LINC (Linear Amplification using Non-Linear Components) amplifiers, where an amplitude modulated signal is firstly converted to a phase modulated signal and a phase conjugate modulated signal before being amplified by non-linear amplifiers. The two amplified signals are then recombined to provide an amplified version of the original signal.

In both these applications obtaining the phase conjugate of the incoming signal is an essential part of the electrical circuit.

Phase conjugation circuitry, to some extent, has limited the commercialisation of both Retro-directive antenna arrays and LINC circuit architectures. For example, prior art phase conjugate circuits for retro-directive arrays use a heterodyning approach involving a signal mixer which relies on a local oscillator (LO) operating at twice the desired input RF (Radio Frequency) frequency. As the RF signal and the signal from the output IF (Intermediate Frequency) ports are the same, or very nearly the same, direct leakage from the RF signal to the IF ports causes significant problems. In addition the LO frequency must be twice the RF frequency so that the down-converted IF output signal is the phase conjugate of the RF input signal. This can be disadvantageous when the RF signal is required to be of very high frequency such as for anti-collision vehicular radars operating at 77 GHz. In this case, the LO frequency would have to be 154 GHz which would be difficult to construct using currently available technology.

LINC amplifiers suffer from general circuit complexity in the phase conjugate sections. Subsequently, LINC amplifiers have not been successfully operated at frequencies of greater than a few 10's of Megahertz mainly for this reason.

Additional problems exist with the prior art associated with phase conjugation circuitry: prominent amongst these are the requirement for:
sophisticated mixer balancing techniques required to prevent unwanted leakage signals corrupting the phase conjugation process. This leads to weak output signal levels since conventional mixer circuits are either passive (and therefore lossy) or limited to the few dB conversion gain that can be achieved with conventional active mixers; and
the need for a local oscillator signal operating at twice the RF signal (as mentioned above).

Other applications for retrodirective (self tracking) array technology include simplex and duplex communication with low earth orbiting, non-geosynchronous satellites and as a low cost means for automatic beam forming as required for modern spatial division multiple access mobile phone wireless communication systems. Further examples are the use of a self-tracking array for automatic alignment of ground stations with high altitude communications platforms or in the creation of agile radar cross-section modification.

Phase locked loop circuits have been widely used since first being proposed in 1922. Since that time, PLL's have been used in instrumentation, space telemetry and many other applications requiring a high degree of noise immunity and narrow bandwidth.

A standard phase lock loop (PLL) circuit comprises a phase detector, a low-pass filter, and an oscillator, usually a voltage-controlled oscillator (VCO). In the case where the oscillator is a VCO, the phase detector outputs a voltage proportional to the phase difference between a PLL input and a feedback signal from the output of the VCO. The low-pass filter acts as an integrator and provides a filtered voltage signal or an error signal which controls the VCO. When the error signal is zero, the VCO operates at a set frequency, known as the free running frequency. When the error signal is not zero, the phase of the PLL input and the feedback signal are no longer in balance and the VCO reacts to the error signal by modifying its output to track the PLL input.

It is an object of the present invention to obviate or mitigate the problems identified above in relation to phase conjugation circuits.

According to a first aspect of the present invention there is provided a circuit arrangement for deriving phase conjugation information from a main input signal of a given frequency comprising:
an input receiving a reference input signal;
at least one phase locked loop circuit comprising an oscillator having a main output signal, an input receiving a PLL input signal, an input receiving a feedback signal from the oscillator and at least one phase detecting means, wherein the phase detection means detects any phase difference between the PLL input signal and the feedback signal and provides a phase control signal to the oscillator.

In one embodiment, the circuit arrangement further comprises a first heterodyne mixer having an input for receiving the main input signal and an input for receiving the main output signal, the first mixer providing the feedback signal and wherein the PLL input signal is the reference input signal.

Preferably the feedback signal is the up-converted mixing product of the first heterodyne mixer.

Preferably, the frequency of the reference input signal is scaled to match the frequency. of the feedback signal.

Further preferably, the feedback signal is scaled.

Preferably, the phase detection means is a digital phase detector.

In one form of the invention, the phase detection means also detects any phase difference between an input receiving the main output signal and an input receiving the reference signal thereby creating a further phase locked loop.

Preferably, the phase detection means comprises:
a first phase detector which detects any phase difference between an input receiving the reference input signal and an input receiving the feedback signal;
a second phase detector which detects any phase difference between an input receiving the reference input signal and an input receiving the main output signal;
an integrator integrating the first phase detector output;
an oscillator heterodyne mixer mixing the integrator output and the second phase detector output;
wherein the oscillator mixer output is the phase detection means output providing a control signal for the oscillator.

In an alternative form of the invention, the phase detection means comprises:
a first phase detection heterodyne mixer mixing an input receiving the reference input signal and an input receiving the feedback signal and having a first phase detection mixer output wherein the first mixer output is the down-converted mixing product of the first mixer;
a second phase detection heterodyne mixer mixing an input receiving the reference input signal and an input receiving the first phase detection mixer output and having a second phase detection mixer output wherein the second phase detection mixer output is the down-converted mixing product of the second phase detection mixer and the phase detection means output providing a control signal for the oscillator.

In alternative form of the invention, a feedback heterodyne mixer mixes an input receiving the main output signal and an input receiving the reference input signal, the feedback signal is the down-converted mixing product of the feedback heterodyne mixer and the PLL input signal is the main input signal, the feedback signal being proportional to the main input signal.

Preferably, the main input signal is scaled by a first divider, the main output signal is scaled by a second divider and the feedback signal scaled by a third divider, the first divider having a scaling value equal to the product of the second and third divider scaling values.

Preferably, an input heterodyne mixer mixes the main input signal and the reference input signal, the PLL input signal is the down-converted mixing product of the input heterodyne mixer and the feedback signal is the main output signal, the main input signal and the main output signal having substantially equal frequencies.

Preferably, a first divider scales the main input signal, a second divider scales the main output signal, the first divider having a scaling value equal to the second divider scaling value.

Preferably the oscillator is a voltage controlled oscillator (VCO).

According to a second aspect of the present invention there is provided a method of deriving phase conjugation information from an input signal, the method comprising detecting phase difference in a phase locked loop (PLL) circuit between an input receiving a feedback signal having a first frequency and an input receiving a PLL input signal of a second frequency which is proportional to the first frequency.

Embodiments of the present invention will now be described with reference to the accompanying drawings, in which;

FIG. 1 shows a schematic diagram of a frequency offset phase conjugating phase locked loop (PLL) circuit;

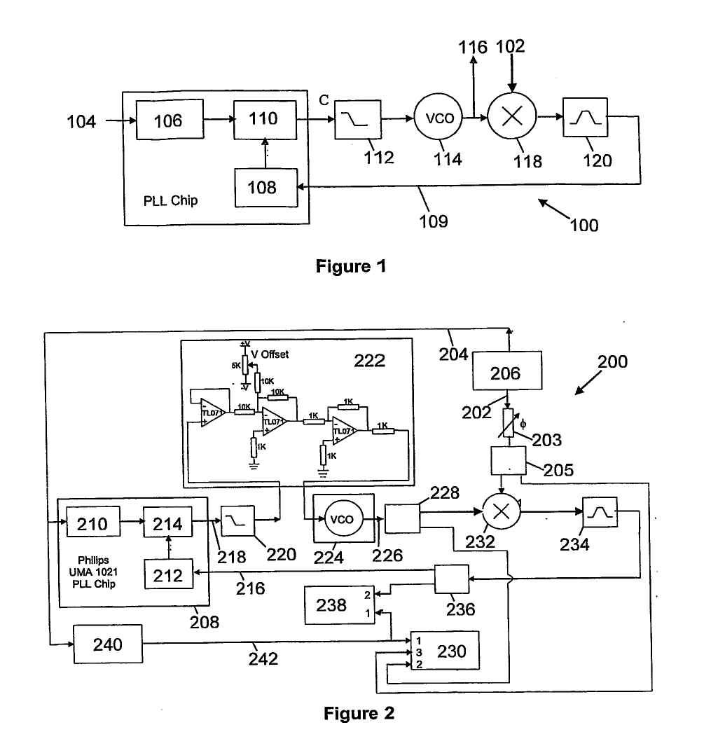

FIG. 2 shows a schematic diagram of a practical implementation of the phase conjugating PLL circuit of FIG. 1;

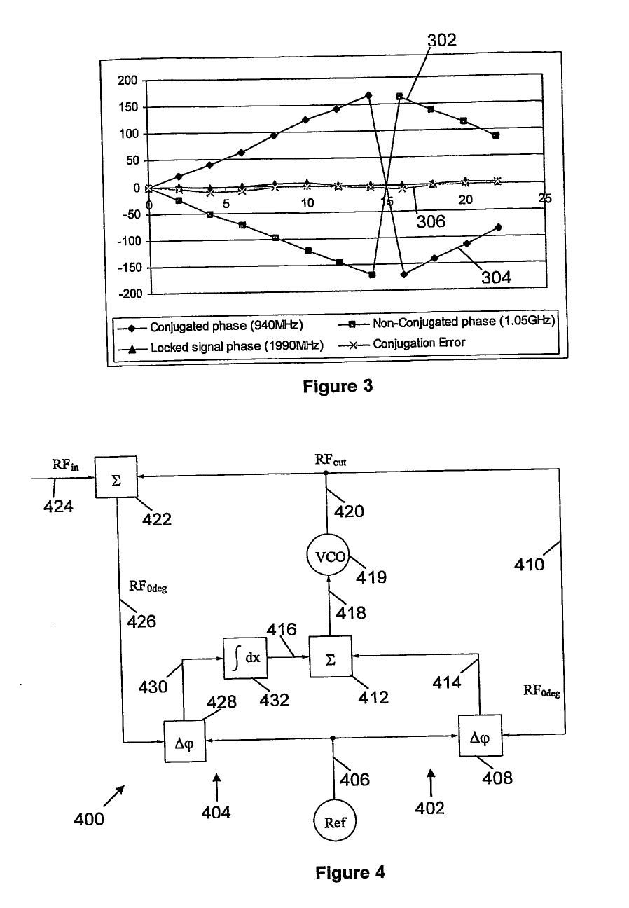

FIG. 3 shows a graphical representation of experimentally derived phase angle of signals in the phase conjugating PLL circuit of FIG. 2;

FIG. 4 shows a schematic diagram of an integrator based phase conjugating PLL circuit;

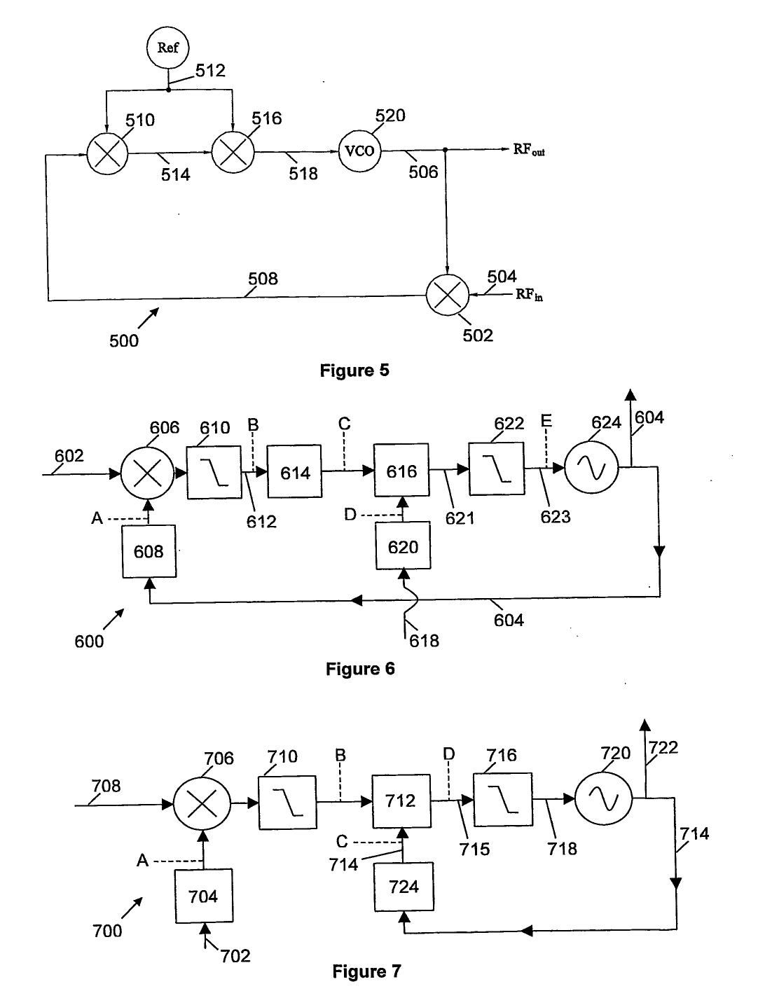

FIG. 5 shows a schematic diagram of a heterodyne mixer based phase conjugating PLL circuit.

FIG. 6 shows a schematic diagram of an alternative embodiment of a phase conjugating PLL circuit.

FIG. 7 shows a schematic diagram of a further alternative embodiment of a phase conjugating PLL circuit.

Referring now to FIG. 1, a frequency offset phase conjugating PLL circuit 100 has a main input signal 102 (Fᵢₙ+φ) and a reference input signal 104 (F_{REF}). A reference divider 106 divides the reference input signal 104 and a main divider 108 divides a feedback signal 109 such that a phase detector 110 receives the divided reference input signal and the divided feedback signal at the same frequency. The phase detector outputs a phase control signal representing a phase difference between the reference input signal and the feedback signal 109. A low-pass loop filter 112 filters, or integrates, the phase control signal to provide a DC control signal. A voltage controlled oscillator (VCO) 114 receives the phase control signal and outputs a VCO signal 116 of a particular frequency (F_{VCO}) and a phase angle (φ) determined by the phase control signal. The VCO signal 116 is also a phase conjugate signal of the main input signal 102 as explained below. A heterodyne mixer 118 mixes the VCO signal 116 and the main input signal 102 to produce the feedback signal 109 which in this case is filtered by a band pass filter 120 to allow selection of the up-converted mixing product of the mixer 118.

The frequency offset phase conjugating PLL circuit 100 works in the following manner:

Up-converted Phase locked Loop without reference divider 106 and main divider 108

Output of mixer 118: F_{IN}+φ+F_{VCO}+φ

Reference Input 104: F_{REF}=F_{IN}+F_{VCO}

At position C: F_{IN}+F_{VCO}=F_{IN}+φ+F_{VCO}+φ
: F_{IN}+F_{VCO}−F_{IN}−φ+F_{VCO}−φ=0
: −φ−φ=0
φ=−φ

VCO signal 116: F_{VCO}+φ=F_{VCO}−φ

Therefore, if F_{VCO}=F_{IN}, the VCO signal 116 is the phase conjugate of the main input signal 102. If F_{VCO}≠F_{IN} then the VCO signal 116 is the offset phase conjugate of the main input signal 102.

The reference divider 106 and the main divider 108 allow the possibility of reducing the required frequency of the reference input signal 104. The phase detector 110 is intended to detect any difference in phase between the feedback signal 109 and the reference input signal 104.

For example:
F_{IN}=1000 Mhz
F_{VCO}=990 Mhz
F_{REF}=10 Mhz
Input to Main divider (up-converted)=1990 Mhz
Output from Main divider=1990/9950=0.2 MHz
Input to Reference divider=10 Mhz
Output from Reference divider=10/50=0.2 MHz

Using this arrangement, the reference input signal 104 at a much smaller frequency than the main input signal 102 is required.

Referring now to FIG. 2, a phase conjugating PLL circuit 200, that is an experimental implementation of the frequency-offset phase conjugating PLL circuit of FIG. 1, is shown. A main input signal 202 and a reference input signal 204 are generated from a first signal synthesiser 206. A phase shifter 203 is introduced to the main input signal 202 so that the main input signal 202 has a different phase angle than that of the reference input signal 204. A first power splitter 205 splits the main input signal 202 so that an oscilloscope 230 can visually display the signal 202 without any losses. A Philips® UMA1021M PLL chip contains a reference input divider 210, a main input divider 212 and a phase detector 214. In this example, the reference input divider 210 divides the reference input signal 204 which is then inputted to the phase detector 214. The main input divider 212 divides a feedback signal 216 which is then also inputted to the phase detector 214. The phase detector produces a phase control signal 218 which represents the phase difference between the reference input signal 204 and the feedback signal 216. A loop filter 220 integrates the phase control signal 218. A unity gain non-inverting summing amplifier 222 ensures the phase control signal 218 is isolated from the phase detector 214 and also allows the phase control signal 218 to be offset as necessary. A Voltage Controlled Oscillator (VCO) 224 has an output signal 226 at a predetermined frequency. The VCO can vary the phase of the output signal 226 dependent on the phase control signal 218. A second power splitter 228 allows the output signal 226 to be displayed on the oscilloscope 230 without any losses within the circuit 200. The output signal 226, when the circuit 200 is phase locked, is now a phase conjugate signal of the main input signal 202. A heterodyne mixer 232 mixes the output signal 226 and the main input signal 202 to produce the feedback signal 216. A band-pass filter 234 filters the feedback signal 216 such that only the up-converted mixing product from the mixer 232 remains. A third power splitter 236 allows the feedback signal to be analysed by a microwave transition analyser (MTA) 238 as well as being connected to the main divider 212 without any losses to the circuit 200. A second signal synthesiser 240 provides a comparison signal 242 to the oscilloscope 230 and the MTA 238 as required. The main input signal 202 and the comparison signal 242 are phase locked to the reference input signal. In use, the first signal synthesiser 206 synthesised the main input signal 202 at a frequency of 1.05 GHz and the reference input signal 204 at 0.01 GHz. The phase shifter 203 introduces a different phase angle to the main input signal 202 than that of the reference input signal 204. The main input signal 202 is then viewed on the oscilloscope 230 via the first power splitter 205. The main output signal 226 is generated by the VCO 224 at a frequency of 0.94 GHz and is also viewed on the oscilloscope 230 via the second power splitter 228. The mixer 232 mixes the main input signal 202 and the main output signal 226. The band-pass filter 234 ensures that only the up-converted mixing product forms the feedback signal 216 at a frequency of 1.99 Ghz. The feedback signal 216 is viewed on the MTA 238 via the third power splitter 236. The main input divider 212 divides the feedback signal 216 by 9950 producing a signal of 200 KHz. The reference divider divide the reference input signal 204 by 50 to also produce a signal of 200 KHz. The phase detector 214 then detects the phase difference between the divided feedback signal 216 and the divided reference input signal 204 to produce the phase control signal 218 which ultimately controls the VCO's 224 phase angle. The second signal synthesiser 240 is used to generate different signals as required for comparison purposes. Therefore, the comparison signal 242 is set to 0.94 GHz for comparison with the main output signal. As the comparison signal 242 is phase locked to the reference input signal 202, the main output signal 226 should be a phase conjugate of the comparison signal and therefore the phase difference can be measured to confirm this. To measure the actual phase of the main input signal 202 after it had been phase shifted by the phase shifter 203, the second synthesised source 240 is set to produce a comparison signal 242 of 1.05 GHz. To further validate that phase conjugation was operating correctly it was important that the feedback signal 216 had constant phase. The second synthesised source 240 is set to produce a comparison signal 242 of 1.99 GHz and the MTA 238 used to analyse the feedback signal 216.

Referring now to FIG. 3 a graphical representation of a non-conjugated phase angle 302 (representing the main input signal 202 of FIG. 2) is matched substantially equally and oppositely to a conjugated angle 304 (representing the output signal 226 of FIG. 2). A conjugation error 306 is also shown representing the error in phase angle in the conjugated angle 304. It can be clearly seen from FIG. 3 that the conjugated angle 304 has only a small conjugation error 306 at any time and that the practical implementation circuit 202 effectively produces a frequency offset phase conjugated output.

Referring now to FIG. 4, an alternative embodiment of a phase conjugation PLL circuit 400 is shown. The circuit 400 has a PLL 402 and a loop 404. A reference signal 406 supplies a reference signal to both the PLL 402 and the loop 404. The PLL 402 has a first phase detector 408 which compares a first feedback signal 410 with the reference signal 406. A summer 412 receives a first phase error signal 414 and a second phase error signal 416 to produce a composite phase control signal 418. A VCO 419 produces an output signal 420 with a phase dependent on the phase control signal 418. A second heterodyne mixer 422 mixes a main input signal 424 with the output signal 420 to produce a second feedback signal 426. A second phase detector 428 compares the phase of the second feedback signal and the reference signal 406 producing a second phase detector output 430. An integrator 432 integrates the second phase detector output 430 producing the second phase error signal 416.

In use, the circuit 400 has a fast acting PLL 402 that establishes a frequency lock. The loop 404 is relatively slower because of the integrator's 432 transfer characteristics. The loop 404 then forces the output signal 420 to the conjugate phase of the main input signal 424.

Referring now to FIG. 5, an alternative embodiment of a phase conjugation PLL circuit 500 is shown. A first heterodyne mixer 502 mixes a main input signal 504 and an output signal 506 to produce a feedback signal 508. The feedback signal 508 is the up-converted mixing product of the first heterodyne mixer 502. A second heterodyne mixer 510 mixes a reference signal 512 with the feedback signal 508 producing an intermediate signal 514. The intermediate signal 514 is the down-converted mixing product of the second heterodyne mixer 510. A third heterodyne mixer 516 mixes the intermediate signal 514 with the reference signal 512 producing a phase control signal 518. The phase control signal 518 is the down-converted mixing product of the third heterodyne mixer 516. A VCO 520 produces an output signal 506 with a phase dependent on the phase control signal 518.

The operation of the circuit 500 is explained below.

Assuming that the circuit 500 is phase locked and the main input signal (RF_{IN}) 504, the output signal (RF_{OUT}) 506 and the reference signal (RF_{REF}) 512 are all the same frequency ω.

The feedback signal 508 is RF_{F}, the intermediate signal 514 is RF_{I} and the phase control signal 518 is RF_{C}.
RF_{REF}=ω+θ_{REF}
RF_{IN}=ω+θ_{IN}
RF_{OUT}=ω+θ_{OUT}
RF_{F}=2ω+θ_{OUT}+θ_{IN}
RF_{I}=ω+θ_{OUT}+θ_{IN}−θ_{REF}
RF_{C}=θ_{OUT}+θ_{IN}−θ_{REF}−θ_{REF}=C
θ_{OUT}=c+2θ_{REF}−θ_{IN}

In the equation above it is shown that the output signal phase is conjugated to the main input signal phase (θ_{OUT}=−θ_{IN}). The term c+2θ_{REF} represents a static phase error introduced by the reference input signal's 512 oscillator. The 2θ_{REF} term may be removed by filtering. The term c represents the control voltage for the VCO 520 and therefore will always be present except where the output frequency is equal to the free-running frequency of the VCO 520. The term c will change as the circuit 500 tracks changes in the main input signal 504 frequency.

For retrodirective antenna arrays this does not pose a problem as relative phase states are important, not absolute phase states. For LINC type amplifier applications any phase error caused by the term c can be accounted for by a prior calibration process across the expected frequency operating range of the circuit.

The circuit 500 can instantaneously phase conjugate as the circuit is made up of heterodyne mixers and does not include integrators or phase detectors which have a finite time determined by the loop dynamics in order to establish a phase lock. As the heterodyne mixers act as the phase detectors, the circuit 500 can operate directly at the microwave and millimetre wave frequencies without the need for dividers or digital phase detection circuitry.

Referring now to FIG. 6, an alternative embodiment of a phase conjugation PLL circuit 600 is shown. A reference input signal (ω_{c}+ψ) 602 and a main output signal (ω+φᵢ) 604 are supplied to a mixer 606. In this example, an output divider 608 divides the main output signal 604 by N₁. A first low-pass filter 610 receives and filters the output of the mixer 606 to extract the down-converted mixing product and produce a feedback signal 612. A feedback divider 614 divides the feedback signal 612 by N₂. A phase detector 616 receives the output from the feedback divider 614.

An input divider 620 receives a main input signal (ω₁+θᵢ) 618 and divides by N₃. The main input signal is then inputted to the phase detector 616.

The phase detector 616 outputs a phase control signal 621 representing a phase difference between the feedback signal 612 and the main input signal 618. A second low-pass filter 622 filters, or integrates, the phase control signal 621 to provide a DC control signal 623. A VCO 624 outputs the main output signal 604 according to the DC control signal 623.

The operation of the circuit 600 is explained below.

At point A the main output signal 604 is divided by the output divider 608:

$$\frac{ω}{{N}_{1}} + \frac{{φ}_{i}}{{N}_{1}}$$

At point B the reference signal 602 is mixed by the mixer 606 with the main output signal 604 after division by the output divider 608 and filtered by the first low-pass filter 610 to extract the down-converted mixing product:

$${ω}_{c} + ψ - \frac{ω}{{N}_{1}} - \frac{{φ}_{i}}{{N}_{1}}$$

At point C the down converted mixing product of the mixer 606 is divided by the feedback divider 614:

$$\frac{{ω}_{c}}{{N}_{2}} + \frac{ψ}{{N}_{2}} - \frac{ω}{{N}_{2} {N}_{1}} - \frac{{φ}_{i}}{{N}_{2} {N}_{1}}$$

At point D the main input signal 618 has been divided by the input divider 620:

$$\frac{{ω}_{1}}{{N}_{3}} + \frac{{θ}_{i}}{{N}_{3}}$$

At point E the phase detector 616 compares the signal at point C and the signal at point D:

$$\frac{{ω}_{c}}{{N}_{2}} + \frac{ψ}{{N}_{2}} - \frac{ω}{{N}_{2} {N}_{1}} - \frac{{φ}_{i}}{{N}_{2} {N}_{1}} - \frac{{ω}_{1}}{{N}_{3}} - \frac{{θ}_{i}}{{N}_{3}}$$

When the circuit 600 has phase lock, the output of the phase detector 616 is zero:

$$\frac{{ω}_{c}}{{N}_{2}} + \frac{ψ}{{N}_{2}} - \frac{ω}{{N}_{2} {N}_{1}} - \frac{{φ}_{i}}{{N}_{2} {N}_{1}} - \frac{{ω}_{1}}{{N}_{3}} - \frac{{θ}_{i}}{{N}_{3}} = 0$$

If

$$\frac{{ω}_{1}}{{N}_{3}} = \frac{{ω}_{c}}{{N}_{2}} - \frac{ω}{{N}_{2} {N}_{1}}$$

and ψ=0, as it is the reference signal phase, then:

$$- \frac{{φ}_{i}}{{N}_{2} {N}_{1}} = \frac{{θ}_{i}}{{N}_{3}}$$

Provided N₃=N₂N₁ then θᵢ=−φᵢ and phase conjugation occurs.

Referring now to FIG. 7, an alternative embodiment of a phase conjugation PLL circuit 700 is shown. A main input signal (ω₁+θᵢ) 702 is divided by an input divider 704 to provide an input for a mixer 706 along with a reference signal (Δf+ψ) 708. A first low-pass filter 710 enables extraction of the down-converted mixing product of the mixer 706. A phase detector 712 receives the down-converted mixing product of the mixer 706 and a feedback signal 714 and outputs a phase control signal 715. A second low-pass filter 716 filters the phase control signal 715 to generate a DC control signal 718. An oscillator 720 receives the DC control signal 720 and generates a main output signal (ω+φᵢ) 722, which, in this case, is also the feedback signal 714. A feedback divider 724 divides the feedback signal 714 before the feedback signal 714 is inputted to the phase detector 712.

The operation of the circuit 700 is explained below.

At point A the main input signal 702 has been divided by the input divider 704:

$$\frac{{ω}_{1}}{{N}_{1}} + \frac{{θ}_{i}}{{N}_{1}}$$

At point B the divided main input signal and the reference signal 708 have been mixed with the down-converted mixing product being extracted:

$$Δ f + ψ - \frac{ω}{{N}_{1}} - \frac{{θ}_{i}}{{N}_{1}}$$

At point C the main output signal 722 has been divided by the feedback divider 724:

$$\frac{ω}{{N}_{2}} + \frac{{φ}_{1}}{{N}_{2}}$$

At point D the phase detector 712 compares the signal at point B and the signal at point C:

$$Δ f + ψ - \frac{{ω}_{1}}{{N}_{1}} - \frac{{θ}_{i}}{{N}_{1}} - \frac{ω}{{N}_{2}} - \frac{{φ}_{i}}{{N}_{2}}$$

When the circuit 700 has phase lock, the output of the phase detector 712 is zero:

$$Δ f + ψ - \frac{{ω}_{1}}{{N}_{1}} - \frac{{θ}_{i}}{{N}_{1}} - \frac{ω}{{N}_{2}} - \frac{{φ}_{i}}{{N}_{2}} = 0$$

If N₁=N₂=N, then ω=ω₁, and ψ=0, as it is the reference signal phase, then:
ΔfN−2ω−θᵢ−φᵢ=0
or,
θᵢ=−φᵢ+(ΔfN−2ω)
So, if ΔfN=2ω, then θᵢ=−φᵢ and phase conjugation occurs.

Improvements and modifications may be incorporated without departing from the scope of the present invention.

1. A circuit arrangement for deriving phase conjugation information from a main input signal of a given frequency comprising:
an input receiving a reference input signal; and
a phase locked loop (PLL) circuit comprising an oscillator having a main output signal, an input receiving a PLL input signal, an input receiving a feedback signal from the oscillator and a phase detecting means,
wherein the phase detection means detects any phase difference between the PLL input signal and the feedback signal and provides a phase control signal to the oscillator.

2. A circuit as claimed in claim 1, wherein a first heterodyne mixer mixes the main input signal and the main output signal to provide the feedback signal and the PLL input signal is the reference input signal.

3. A circuit as claimed in claim 2, wherein the feedback signal is the up-converted mixing product of the first heterodyne mixer.

4. A circuit as claimed in claim 1, wherein the frequency of the reference input signal is scaled to match the frequency of the feedback signal.

5. A circuit as claimed in claim 1, wherein the feedback signal is scaled.

6. A circuit as claimed in claim 1, wherein the phase detection means is a digital phase detector.

7. A circuit as claimed in claim 1, wherein the phase detection means also detects any phase difference between an input receiving the main output signal and an input receiving the reference signal thereby creating a further phase locked loop.

8. A circuit as claimed in claim 7, wherein the phase detection means comprises:
a first phase detector which detects any phase difference between an input receiving the reference input signal and an input receiving the feedback signal;
a second phase detector which detects any phase difference between an input receiving the reference input signal and an input receiving the main output signal;
an integrator integrating the first phase detector output;
an oscillator heterodyne mixer for mixing the integrator output and the second phase detector output;
wherein the oscillator mixer output is the phase detection means output providing a control signal for the oscillator.

9. A circuit as claimed in claim 1, wherein the phase detection means comprises:
a first phase detection heterodyne mixer mixing an input receiving the reference input signal and an input receiving the feedback signal and having a first phase detection mixer output wherein the first mixer output is the down-converted mixing product of the first mixer;
a second phase detection heterodyne mixer mixing an input receiving the reference input signal and an input receiving the first phase detection mixer output and having a second phase detection mixer output wherein the second phase detection mixer output is the down-converted mixing product of the second phase detection mixer and the phase detection means output providing a control signal for the oscillator.

10. A circuit as claimed in claim 1, wherein a feedback heterodyne mixer mixes an input receiving the main output signal and an input receiving the reference input signal, the feedback signal is the down-converted mixing product of the feedback heterodyne mixer and the PLL input signal is the main input signal, the feedback signal being proportional to the main input signal.

11. A circuit as claimed in claim 10, wherein the main input signal is scaled by a first divider, the main output signal is scaled by a second divider and the feedback signal scaled by a third divider, the first divider having a scaling value equal to the product of the second and third divider scaling values.

12. A circuit as claimed in claim 1, wherein an input heterodyne mixer mixes the main input signal and the reference input signal, the PLL input signal is the down-converted mixing product of the input heterodyne mixer and the feedback signal is the main output signal, the main input signal and the main output signal having substantially equal frequencies.

13. A circuit as claimed in claim 12, wherein a first divider scales the main input signal, a second divider scales the main output signal, the first divider having a scaling value equal to the second divider scaling value.

14. A circuit as claimed in claim 1, wherein the oscillator is a voltage controlled oscillator (VCO).

15. A method of deriving phase conjugation information from an input signal, the method comprising detecting phase difference in a phase locked loop (PLL) circuit between a feedback signal having a first frequency and a PLL input signal of a second frequency which is proportional to the first frequency.
